(19) United States
(12) Patent Application Publication
(10) Pub. No.: US 2013/0027898 A1
(43) Pub. Date: Jan. 31, 2013

(54) SURFACE CONTACT CARD HOLDER FOR ELECTRONIC DEVICE

(71) Applicants: DE-HUI YUAN, Shenzhen City (CN); ZHI-GANG PENG, Shenzhen City (CN)

(72) Inventors: DE-HUI YUAN, Shenzhen City (CN); ZHI-GANG PENG, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/334,440

(22) Filed: Dec. 22, 2011

(30) Foreign Application Priority Data
Jul. 29, 2011 (CN) 201110215439.2

(51) Int. Cl. H05K 7/00

(52) U.S. Cl. 361/807; 211/26.2

(57) ABSTRACT

A holder for a surface contact card includes a tray and a sliding member. The tray defines a first receiving space and a second receiving space, the surface contact card is configured for being received in the first receiving space. The sliding member includes a main body and a handle portion, the main body is slidably received in the second receiving space, and the tray prevents the sliding member from accidentally moving out of the tray.

### BACKGROUND

1. Technical Field

The present disclosure generally relates to card use in electronic devices, and particularly, to a surface contact card holder for an electronic device.

2. Description of Related Art

Surface contact cards having special circuits are widely used in portable electronic devices to enhance or specialize the functions of the portable electronic devices. For example, a subscriber identity module (SIM) card in a mobile phone can dedicate the mobile phone's functions to the SIM card owner. By changing SIM cards, a single mobile phone can be used by many different SIM card owners as a personal phone.

Although surface contact card holders may be simple, it can be difficult for the surface contact card to be removed from the surface contact card holder.

Therefore, there is room for improvement within the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the surface contact card holder. Moreover, in the drawings, like reference numerals designate corresponding parts throughout the several views.

FIG. 1 is an exploded, isometric view of a surface contact card holder in accordance with an exemplary embodiment.

FIG. 2 is an isometric view of the assembled surface contact card holder.

FIG. 3 is a schematic view of the surface contact card holder with the surface contact card.

FIG. 4 is an open schematic view of the surface contact card holder showing the surface contact card in place.

FIG. 5 is an exploded, isometric view of a surface contact card holder in accordance with another exemplary embodiment.

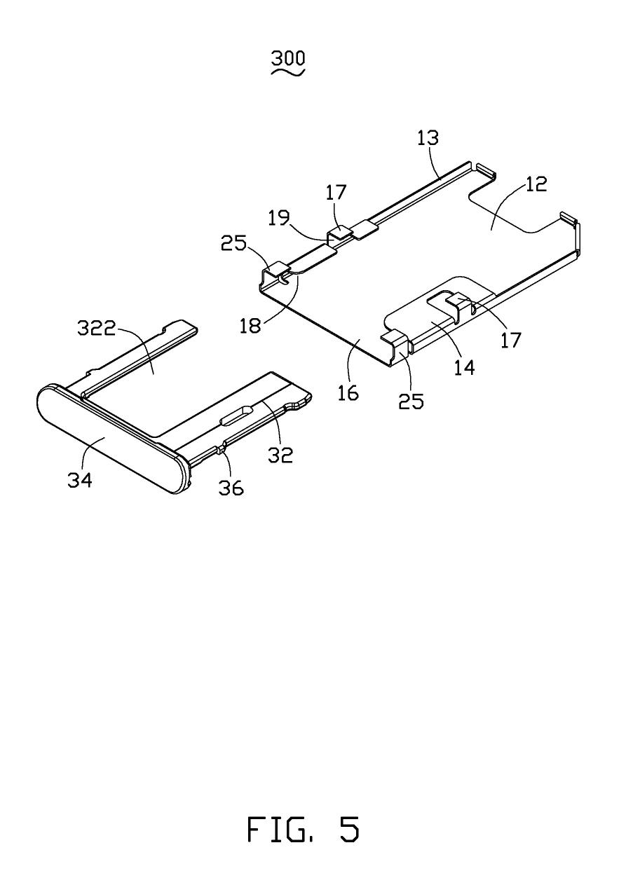

FIG. 6 is an isometric view of the assembled surface contact card holder in FIG. 5.

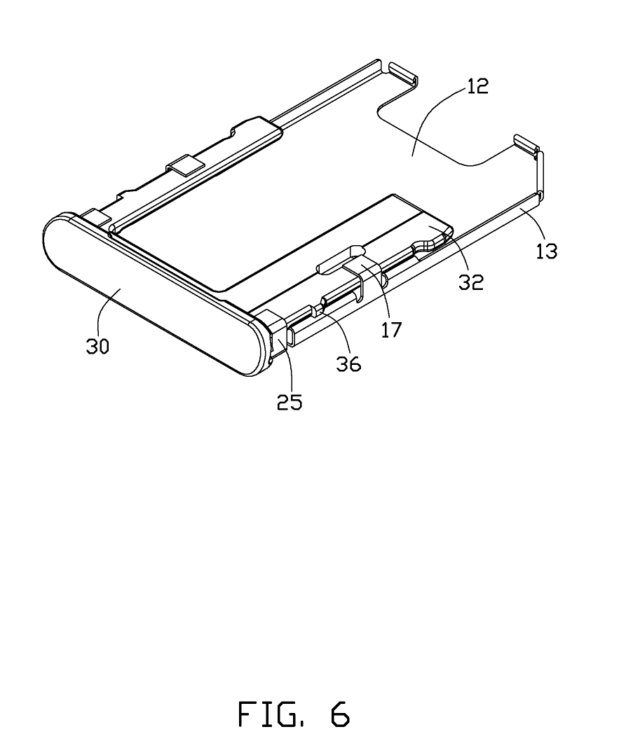

### DETAILED DESCRIPTION

The disclosed surface contact card holder can seat surface contact cards such as SIM cards, compact flash cards (CFs), multimedia cards (MMCs), and others. The disclosed electronic device, shown in the exemplary embodiment as a mobile phone, can alternatively be a personal digital assistant (PDA), camera, recorder, or other device remaining well within the scope of the disclosure.

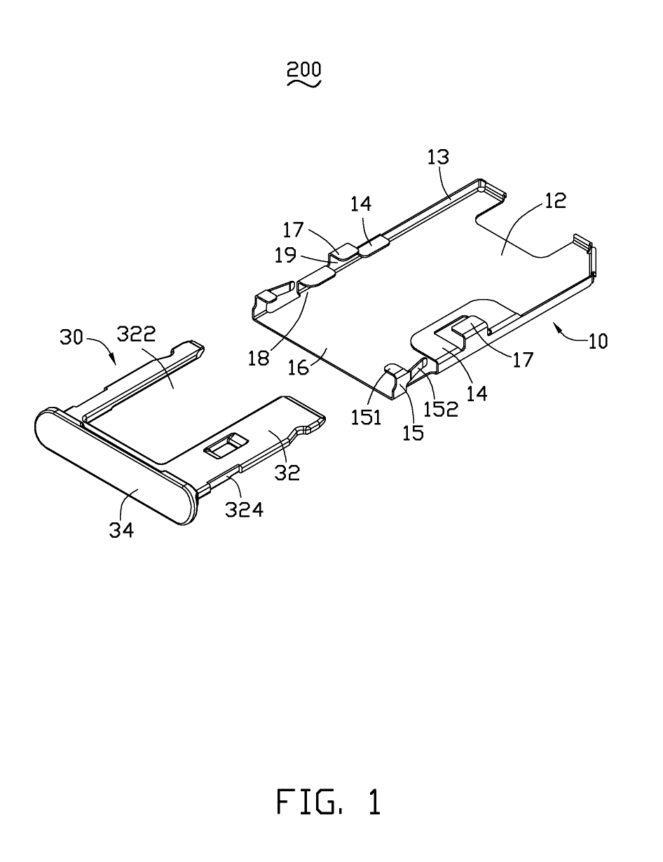

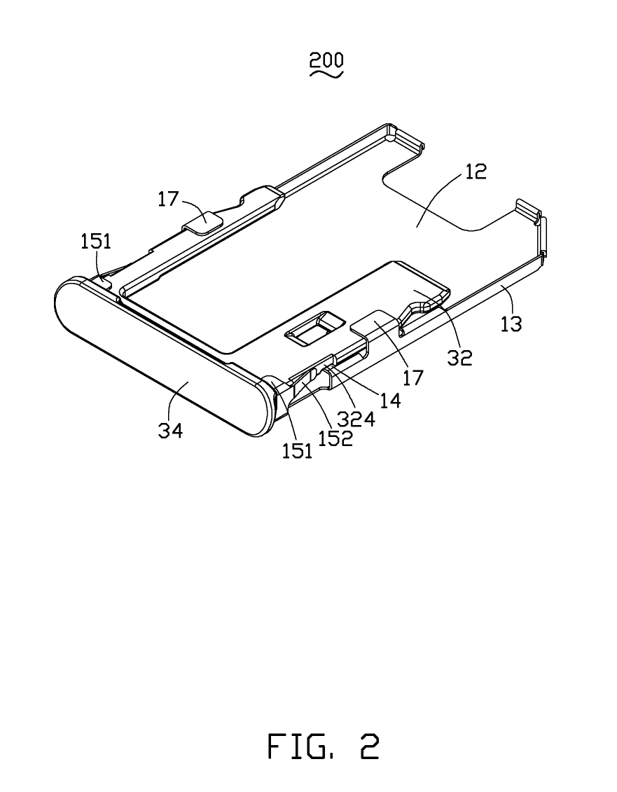

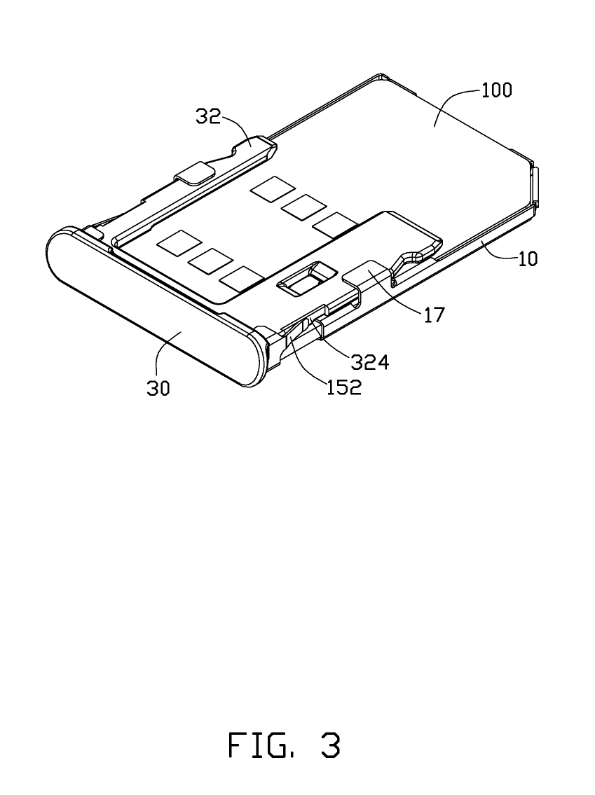

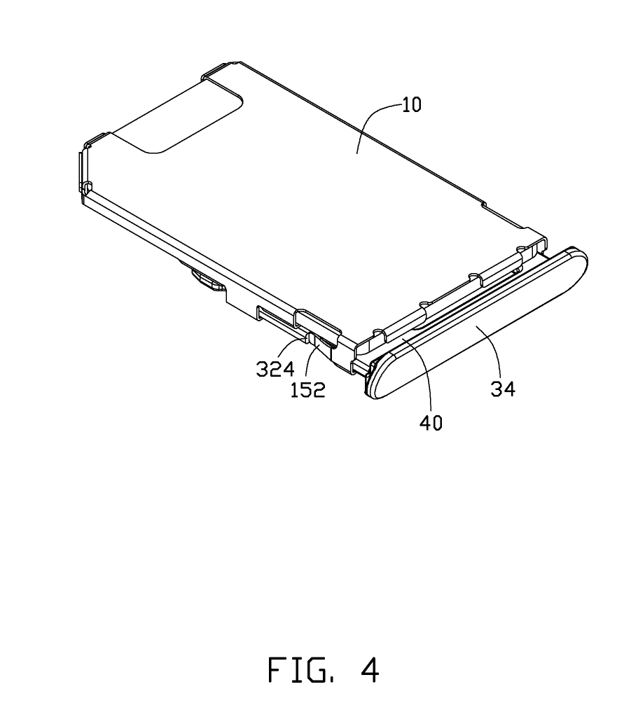

FIGS. 1 to 4 show a surface contact card holder 200 configured for receiving a surface contact card 100. Referring to FIGS. 1 and 2, the surface contact card holder 200 includes a tray 10 and a sliding member 30. The sliding member 30 is slidably positioned on the tray 10.

The tray 10 can be assembled in a housing of an electronic device or be integrally formed with the housing of the electronic device. The tray 10 includes a bottom plate 12, a number of side edges 13, two supporting plates 14, two limiting portions 15, an entrance 16, and two latching portions 17. The tray 10 is made of metal, and is formed by punching to a predetermined shape.

The side edges 13 perpendicularly extend from opposite sides and from one end of the bottom plate 12 opposite to the entrance 16. The supporting plates 14 horizontally extend from opposite side edges 13, and are parallel to the bottom plate 12. The supporting plates 14 with the side edges 13 and the bottom plate 12 cooperatively define a first receiving space 18 for receiving the surface contact card 100.

The limiting portions 15 are formed at two sides of the tray 10 adjacent to the entrance 16. A tab 151 and a finger 152 branch from each limiting portion 15. The tabs 151 are opposite to each other, and are parallel to the bottom plate 12. Each finger 152 extends towards a support plate 14, and inwards into the tray 10. Each of the latching portions 17 is formed on a support plate 14, and is higher than the supporting plate 14. The height of the limiting portions 15 relative to the bottom plate 12 is substantially equal to the height of the latching portions 17. A second receiving space 19 is defined between the supporting plates 14, the limiting portions 15 and the latching portions 17.

The sliding member 30 includes a main body 32 and a handle portion 34. The main body 32 is slidably received in the second receiving space 19. The main body 32 defines an opening 322 configured for allowing a connector to electrically connect to the surface contact card 100. Each of the two sides of the main body 32 define a notch 324. The fingers 152 are for latching in the notches 324.

To assemble the surface contact card holder 200, the main body 32 of the sliding member 30 is slidably received in the second receiving space 19. The supporting plates 14 support one side of the main body 32, and the tabs 151 and the latching portions 17 abut against the other side of the main body 32. The fingers 152 latch in the notches 324 to prevent the sliding member 30 falling out of the tray 10.

To insert the surface contact card 100 into the holder 200, the handle portion 34 is pulled away from the tray 10 until the fingers 152 abut against one end of the notches 324. A gap 40 is defined between the handle portion 34 and one end of the tray 10. The surface contact card 100 is inserted into a first receiving space 18 of the tray 10. Then, the tray 10 is slidably received in the second receiving groove 19. The surface contact card 100 and the sliding member 30 are received in two different receiving spaces, therefore when the sliding member 30 slides relative to the tray 10, the sliding member 30 does not force the surface contact card 100 to move. This structure allows the surface contact card 100 to be held steadily in the tray 10.

In another embodiment, the surface contact card holder 300 is generally the same as the surface contact card holder 200 of the first embodiment. In the second embodiment, the tray 10 includes two L-shaped limiting portions 25 and the sliding member 30 includes two elastic protrusions 36. A width between the limiting portions 25 is slightly smaller than the tray 10. When the sliding member 30 is received in the tray 10, the limiting portions 25 impede the protrusions 36 and prevent the sliding member 30 falling out of the tray 10.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A holder for a surface contact card, comprising:
a tray defining a first receiving space and a second receiving space, the surface contact card configured for being received in the first receiving space;
a sliding member including a main body and a handle portion, the main body slidably received in the second receiving space, and the tray preventing the sliding member from separating from the tray.

2. The holder as claimed in claim 1, wherein the tray includes a bottom plate and a plurality of supporting plates, the supporting plates and the bottom plate cooperatively define the first receiving space.

3. The holder as claimed in claim 2, wherein a plurality of latching portions are formed on the supporting plates, and are higher than the support plates, the support plates and the latching portions cooperatively defines the second receiving space.

4. The holder as claimed in claim 3, wherein the tray includes two limiting portions formed at two sides thereof, each limiting portion branches a tab and a finger, the tabs are opposite to each other, and each finger extends toward a corresponding support plate, and is tilted into the tray.

5. The holder as claimed in claim 4, wherein two sides of the main body respectively define a notch, and the fingers are latched in the notches.

6. The holder as claimed in claim 3, wherein the tray includes two L-shaped limiting portions, the sliding member includes two protrusions, a width between the limiting portions is slightly smaller than the tray for allowing the limiting portions to stop the protrusions.

7. An electronic device comprising a holder for a surface contact card, the holder mounted on the portable electronic device and comprising:
a tray defining a first receiving space and a second receiving space, the surface contact card configured for being received in the first receiving space;
a sliding member including a main body and a handle portion, the main body slidably received in the second receiving space, and the tray preventing the sliding member from separating from the tray.

8. The electronic device as claimed in claim 7, wherein the tray includes a bottom plate and a plurality of supporting plates, the supporting plates and the bottom plate cooperatively define the first receiving space.

9. The electronic device as claimed in claim 8, wherein a plurality of latching portions are formed on the supporting plates, and are higher than the support plates, the support plates and the latching portions cooperatively defines the second receiving space.

10. The electronic device as claimed in claim 9, wherein the tray includes two L-shaped limiting portions, the sliding member includes two protrusions, a width between the limiting portions is slightly smaller than the tray for allowing the limiting portions to stop the protrusions.
